(19) United States
(12) Patent Application Publication
(10) Pub. No.: US 2024/0029178 A1
(43) Pub. Date: Jan. 25, 2024

(54) METHOD FOR TESTING ENERGY EFFICIENCY OF DATA CENTER

(71) Applicants: China National Institute of Standardization, Beijing (CN); Hefei General Machinery & Electrical Products Inspection Institute, Hefei (CN)

(72) Inventors: Ling LIN, Beijing (CN); Yanyan PENG, Beijing (CN); Baogang XIE, Hefei (CN); Haoxin LIN, Beijing (CN); Min FANG, Hefei (CN); Yujuan XIA, Beijing (CN); Jizhou JIANG, Hefei (CN); Tingting HE, Beijing (CN); Hongxi XIE, Hefei (CN); Xiaolin YU, Hefei (CN); Jingyao YU, Beijing (CN); Yang GUO, Hefei (CN)

(21) Appl. No.: 18/184,183

(22) Filed: Mar. 15, 2023

(30) Foreign Application Priority Data
Jul. 25, 2022 (CN) 202210877571.8

(51) Int. Cl. G06Q 50/06; G01R 21/00

(52) U.S. Cl. CPC G06Q 50/06; G01R 21/00

(57) ABSTRACT

The present invention relates to the technical field of energy efficiency of data center, particularly to a method for testing energy efficiency of data center. It consists of the test conditions, the point positions for testing and the computational formulas, wherein, the test conditions include the test environment and the precision or accuracy of various instruments, and the point positions for testing consist of the point position for measuring electricity consumption, or the point positions for measuring temperature, relative humidity and illuminance. Furthermore, the computational formulas consist of the design value and the measured value of ratio of electricity consumption of the data center and their determination conditions. Compared with the existing technology, the present invention can effectively test the energy efficiency of the data center by calculating the design value and measured value of ratio of electricity consumption of the data center, and further provide a scientific basis for measuring and auditing energy consumption of various modules deployed in the data center including independent power distribution, air cooling, electric air conditioning.

### TECHNICAL FIELD

The present invention relates to the technical field of energy efficiency of data center, particularly to a method for testing energy efficiency of data center.

### BACKGROUND TECHNOLOGY

Regarding to the aforesaid invention, the new data center refers to the data center which is commenced based upon new project approval and completed by the construction unit according to specified procedures, and the alteration of data center refers to altering the existing building into a data center, or rebuilding a new data center by utilizing computer room of existing data center. Furthermore, the expansion of data center refers to employing various method, including adding more cabinets to the data center or improving electricity consumption of cabinets to expand the service capacity of the data center by the construction unit, and the edge data center refers to a data center, which is small-scale and deployed on the edge of the network closing to the user end for the purpose of implementing several functions including edge data computing, storage and forwarding, wherein, the scale of single room shall not exceed 100 standard racks.

Against the deficiency of existing technology, the fact shows that there is no method is available for conducting energy consumption measurement, energy efficiency computing and audit of new and altered or expanded data centers, or those of the single room or modular unit of the data center equipped with independent power distribution equipment, air cooling and electric air conditioning facilities.

Thus, for the purpose of solving the aforesaid problem, the present invention proposes a method for testing energy efficiency of data center which can calculate the electricity consumption and the ratio of electricity consumption of the data center effectively by virtue of developing a series of computational formulas and testing methods. By this, it may fill the gap of the existing market.

### SUMMARY OF THE INVENTION

The present invention is especially designed to cover the technical defects, which can calculate the electricity consumption and the ratio of electricity consumption of the data center effectively by virtue of developing a series of computational formulas and testing methods. By this, it may fill the gap of the existing market.

In order to achieve the aforesaid objective, the present invention proposes a method for testing energy efficiency of data center, including the test conditions, the point positions for testing and the computational formulas, wherein, the test conditions include the test environment and the precision or accuracy of various instruments, and the point positions for testing consist of the point position for measuring electricity consumption, or the point positions for measuring temperature, relative humidity and illuminance. Furthermore, the computational formulas consist of the design value and the measured value of ratio of electricity consumption of the data center and their determination conditions;

The test environment means that the temperature, the relative humidity, and the illuminance of the data center must be subject to the relevant requirements of GB50174 during testing;
The precision or accuracy of instruments and meters shall be subject to the following requirements:
The accuracy of electric energy metering instrument shall be in Class 1;
The accuracy of current transformer shall be in Class 0.5;
The accuracy of power meter shall be in Class 0.5;
The accuracy of voltage transformer shall be in Class 0.5;
The accuracy of temperature measuring instrument shall be within ±0.5° C.;
The accuracy of relative humidity measuring instrument shall be within ±5%;
The accuracy of illuminometer shall be in class 1 at least, and the relative error of indicating value shall be ≤±4%;

The point position for measuring electricity consumption must be the position where may collect and regulate the electricity consumption data of the data center as well as can obtain the data required for determining the ratio of electricity consumption of the data center;

The point positions for measuring temperature, relative humidity and illuminance consist of indoor and outdoor point positions for measuring. Wherein, the indoor point positions for measuring shall be subject to the relevant provisions of GB50462 and the outdoor point positions for measuring shall be centered and lm away from the windward side of the equipment which impacts on the cooling performance. In addition, if there are multiple devices, the mean value of temperature shall be adopted under the condition of avoiding the impact of the cooling equipment on the temperature measurement;

The design value of ratio of electricity consumption of the data center shall be calculated as per the following formula:

$${R}_{D} = \frac{{E}_{D}}{{E}_{D I T}}$$

Wherein, the R_{D} refers to the design value of ratio of electricity consumption of the data center and the E_{D} refers to the planning design value of total electricity consumption, as well as the E_{DIT} refers to the planning design value of electricity consumption of the information equipment, all of which shall be expressed in kW/h;

In addition, the measured values of ratio of electricity consumption of the data center, consisting of the calibration value of total electricity consumption and the calibration value of electricity consumption of the information equipment, shall be calculated as per the following formula:

S1. According to the actual operating load of the data center, the total power of the data center and the power of information equipment shall be measured continuously respectively based upon selecting different time intervals including the characteristic operating points within a year. Wherein, the continuous measurement must be done for 12 h at least under the stable operation of the refrigeration and information system, meanwhile, the time interval for multiple measurements shall not be more than 2 min. Furthermore, it is prohibited to change the number of servers and the basic facilities including cooling devices and power distribution equipment deployed in the data center, also the refrigeration mode shall not be switched;

S2. The power measured under the test condition that is within ±2° C. of the stable characteristic operating point shall be adopted as valid data, then, the arithmetic means of the total power and the valid data of the power of information equipment shall be calculated respectively, after that, the corresponding power value of such operating point can be worked out;

S3. As to those data centers equipped with data monitoring system of annual electricity consumption and monitoring facility with appropriate accuracy, the annual electricity consumption data shall be measured and recorded at the point positions for measuring electricity consumption, meanwhile, the data of ratio of electricity consumption obtained from two data centers shall be monitored. One of them represents the measured value obtained by virtue of the characteristic operating condition method, which is calculated as per the formula of

$${R}_{M 1} = \frac{{E}_{C}}{{E}_{CIT}}$$

and with the data of total power and the power data of the information equipment collected according to the testing condition related to the ratio of electricity consumption of the data center and the test frequency. The other one represents the annual measured value of the ratio of electricity consumption of the data center, which is calculated with the data of annual electricity consumption as per the formula of

$${R}_{M 2} = \frac{E}{{E}_{IT}} ;$$

The calibration value of the total electricity consumption shall be calculated as per the following formula:

E_{c}=8760×TₐPₐ+8760×T_{b}P_{b}+8760×T_{c}P_{c}+8760×T_{d}P_{d}+8760×TₑPₑ, wherein, E_{c} represents the calibration value of total electricity consumption, which is expressed in kw/h; and Pa˜Pe represent the total power of the data center measured according to various operating conditions, all of which are expressed in kw; furthermore, Ta˜Te represent the temperature distribution coefficients, which indicate the percent of time of each temperature range represented by characteristic operating point distributed in certain region in the year; and the number 8760 refers to the number of hours in the year, which is expressed in h; The calibration value of electricity consumption of the information equipment shall be calculated as per the following formula:

E_{CIT}=8760×TₐP_{aIT}+8760×T_{b}P_{bIT}+8760×T_{c}P_{cIT}+8760×T_{d}P_{dIT}+8760×TₑP_{eIT}

Wherein, E_{cit} represents the calibration value of electricity consumption of the information equipment, which is expressed in kw/h; P_{aIT}˜P_{eIT} represents the power of information equipment deployed in the data center, which is measured under operating conditions and expressed in kw;

The measured value of ratio of electricity consumption of the data center shall be calculated as per the following formula:

$${R}_{M 1} = \frac{{E}_{C}}{{E}_{CIT}} ,$$

wherein, Rₘ₁ represents the measured value of ratio of electricity consumption of the data center, which is measured by virtue of characteristic operating condition method and according to special operating condition mode; In addition, E_{c} represents the calibration value of total electricity consumption and EcIT represents the calibration value of electricity consumption of the information equipment, all of which are expressed in kw/h;

$${R}_{M 2} = \frac{E}{{E}_{IT}} ,$$

wherein, Rₘ₂ represents the annual measured value of ratio of electricity consumption of the data center calculated according to the annual electricity consumption, which is non-dimensional; E represents the annual measured value of annual electricity consumption, which is expressed in kw/h; The determination conditions consist of:

The design value of ratio of electricity consumption of the data center, the measured value obtained by virtue of characteristic operating condition method and the annual measured value shall be subject to corresponding regulations of value classes;

The measured value of ratio of electricity consumption of the data center obtained by virtue of characteristic operating condition method and the annual measured value shall be less than 1.05 times of the design value.

Compared with the existing technology, the present invention can effectively test the energy efficiency of the data center by calculating the design value and measured value of ratio of electricity consumption of the data center, and further provide a scientific basis for measuring and auditing energy consumption of various modules deployed in the data center including independent power distribution, air cooling, electric air conditioning.

### BRIEF DESCRIPTION OF THE DRAWINGS

FIG. 1 refers to the schematic diagram of points for measuring the electricity consumption of the data center of the present invention;

FIG. 2 refers to the schematic diagram of testing condition of ratio of electricity consumption of the data center of the present invention;

FIG. 3 refers to the schematic diagram of collection of key experimental parameters utilized by the embodiment and its processing list;

FIG. 4 refers to the schematic diagram of the test data obtained from the characteristic operating points of a data center located in Shanghai which is described in the embodiment of the present invention;

### DETAILED DESCRIPTION OF THE EMBODIMENTS

The text below will describe the present invention in detail in conjunction with the drawings.

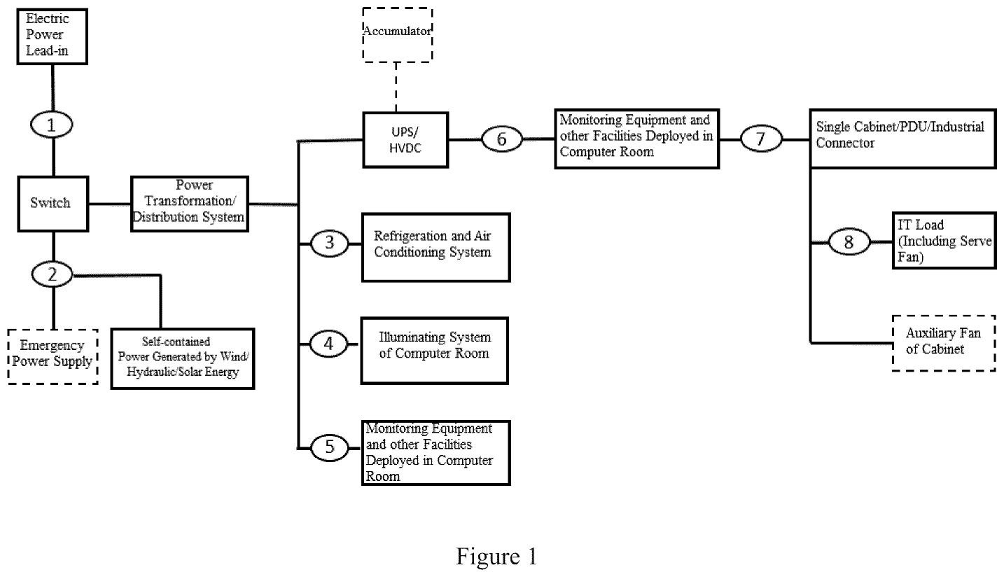

Referring to FIGS. 1 to 4, the present invention proposes a method for testing energy efficiency of data center, including the test conditions, the point positions for testing and the computational formulas, wherein, the test conditions include the test environment and the precision or accuracy of various instruments, and the point positions for testing consist of the point position for measuring electricity consumption, or the point positions for measuring temperature, relative humidity and illuminance. Furthermore, the computational formulas consist of the design value and the measured value of ratio of electricity consumption of the data center and their determination conditions;

The test environment means that the temperature, the relative humidity, and the illuminance of the data center must be subject to the relevant requirements of GB50174 during testing;
The precision or accuracy of instruments and meters shall be subject to the following requirements:
The accuracy of electric energy metering instrument shall be in Class 1;
The accuracy of current transformer shall be in Class 0.5;
The accuracy of power meter shall be in Class 0.5;
The accuracy of voltage transformer shall be in Class 0.5;
The accuracy of temperature measuring instrument shall be within ±0.5° C.;
The accuracy of relative humidity measuring instrument shall be within ±5%;
The accuracy of illuminometer shall be in class 1 at least, and the relative error of indicating value shall be ≤±4%;
As shown in FIG. 1, the point position for measuring electricity consumption must be the position where may collect and regulate the electricity consumption data of the data center as well as can obtain the data required for determining the ratio of electricity consumption of the data center;

The point positions for measuring temperature, relative humidity and illuminance consist of indoor and outdoor point positions for measuring. Wherein, the indoor point positions for measuring shall be subject to the relevant provisions of GB50462 and the outdoor point positions for measuring shall be centered and lm away from the windward side of the equipment which impacts on the cooling performance. In addition, if there are multiple devices, the mean value of temperature shall be adopted under the condition of avoiding the impact of the cooling equipment on the temperature measurement; The design value of ratio of electricity consumption of the data center shall be calculated as per the following formula:

$${R}_{D} = \frac{{E}_{D}}{{E}_{D I T}}$$

Wherein, the R_{D} refers to the design value of ratio of electricity consumption of the data center and the E_{D} refers to the planning design value of total electricity consumption, as well as the E_{DIT} refers to the planning design value of electricity consumption of the information equipment, all of which shall be expressed in kW/h;

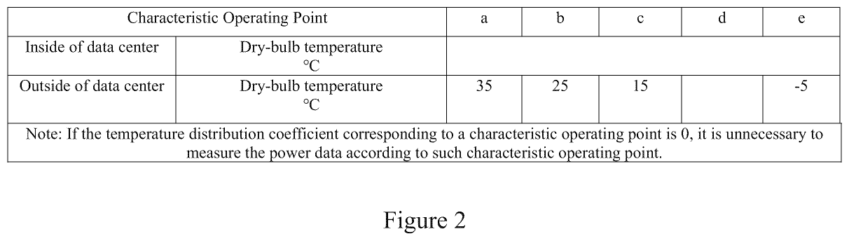

As shown in FIG. 2, the measured values of ratio of electricity consumption of the data center, consisting of the calibration value of total electricity consumption and the calibration value of electricity consumption of the information equipment, shall be calculated as per the following formula:

S1. According to the actual operating load of the data center, the total power of the data center and the power of information equipment shall be measured continuously respectively based upon selecting different time intervals including the characteristic operating points within a year. Wherein, the continuous measurement must be done for 12 h at least under the stable operation of the refrigeration and information system, meanwhile, the time interval for multiple measurements shall not be more than 2 min. Furthermore, it is prohibited to change the number of servers and the basic facilities including cooling devices and power distribution equipment deployed in the data center, also the refrigeration mode shall not be switched;

S2. The power measured under the test condition that is within ±2° C. of the stable characteristic operating point shall be adopted as valid data, then, the arithmetic means of the total power and the valid data of the power of information equipment shall be calculated respectively, after that, the corresponding power value of such operating point can be worked out;

S3. As to those data centers equipped with data monitoring system of annual electricity consumption and monitoring facility with appropriate accuracy, the annual electricity consumption data shall be measured and recorded at the point positions for measuring electricity consumption, meanwhile, the data of ratio of electricity consumption obtained from two data centers shall be monitored. One of them represents the measured value obtained by virtue of the characteristic operating condition method, which is calculated as per the formula of

$${R}_{M 1} = \frac{{E}_{C}}{{E}_{CIT}} ,$$

and with the data of total power and the power data of the information equipment collected according to the testing condition related to the ratio of electricity consumption of the data center and the test frequency. The other one represents the annual measured value of the ratio of electricity consumption of the data center, which is calculated with the data of annual electricity consumption as per the formula of

$${R}_{M 2} = \frac{E}{{E}_{IT}} ;$$

The calibration value of the total electricity consumption shall be calculated as per the following formula:
E_{c}=8760×TₐPₐ+8760×T_{b}P_{b}+8760×T_{c}P_{c}+8760×T_{d}P_{d}+8760×TₑPₑ, wherein, E_{c} represents the calibration value of total electricity consumption, which is expressed in kw/h; and Pa˜Pe represent the total power of the data center measured according to various operating conditions, all of which are expressed in kw; furthermore, Ta˜Te represent the temperature distribution coefficients, which indicate the percent of time of each temperature range represented by characteristic operating point distributed in certain region in the year; and the number 8760 refers to the number of hours in the year, which is expressed in h;
The calibration value of electricity consumption of the information equipment shall be calculated as per the following formula:

E_{CIT}=8760×TₐP_{aIT}+8760×T_{b}P_{bIT}+8760×T_{c}P_{cIT}+8760×T_{d}P_{dIT}+8760×TₑP_{eIT}

Wherein, E_{cit} represents the calibration value of electricity consumption of the information equipment, which is expressed in kw/h; P_{aIT}˜P_{eIT} represents the power of information equipment deployed in the data center, which is measured under operating conditions and expressed in kw;
The measured value of ratio of electricity consumption of the data center shall be calculated as per the following formula:

$${R}_{M 1} = \frac{{E}_{C}}{{E}_{CIT}} ,$$

wherein, R m i represents the measured value of ratio of electricity consumption of the data center, which is measured by virtue of characteristic operating condition method and according to special operating condition mode; In addition, E_{c} represents the calibration value of total electricity consumption and EcIT represents the calibration value of electricity consumption of the information equipment, all of which are expressed in kw/h;

$${R}_{M 2} = \frac{E}{{E}_{IT}} ,$$

wherein, Rₘ₂ represents the annual measured value of ratio of electricity consumption of the data center calculated according to the annual electricity consumption, which is non-dimensional; E represents the annual measured value of annual electricity consumption, which is expressed in kw/h;
The determination conditions consist of:
The design value of ratio of electricity consumption of the data center, the measured value obtained by virtue of characteristic operating condition method and the annual measured value shall be subject to corresponding regulations of value classes;

The measured value of ratio of electricity consumption of the data center obtained by virtue of characteristic operating condition method and the annual measured value shall be less than 1.05 times of the design value.

Embodiment:

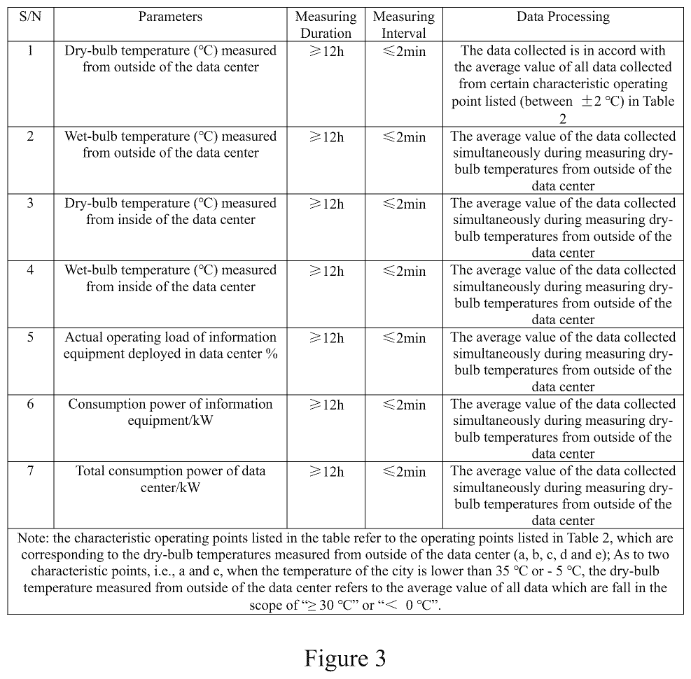

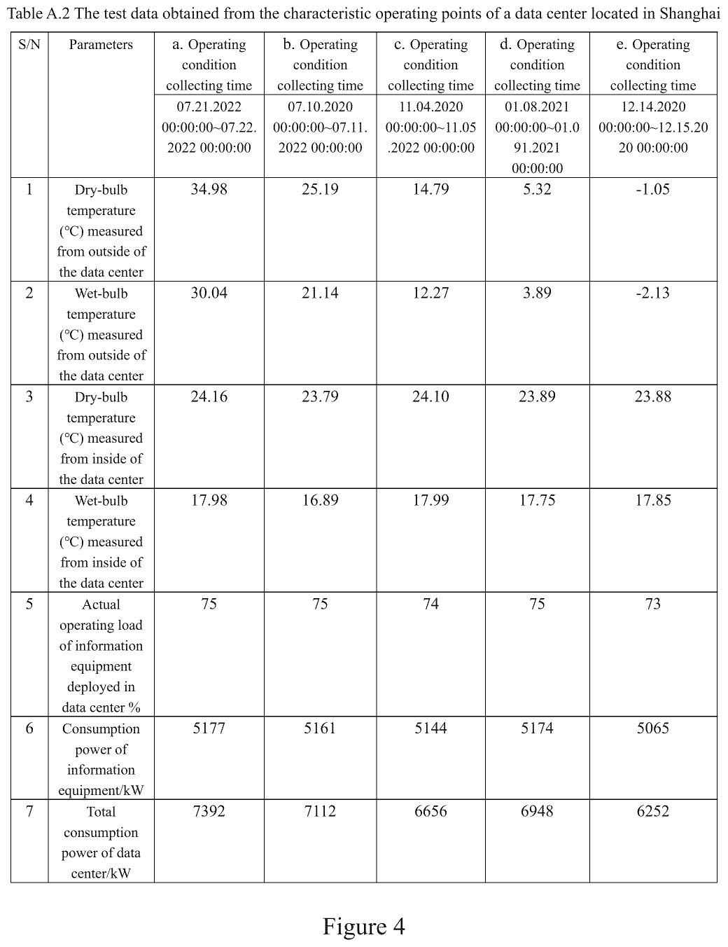

The test was conducted according to the method for testing the measured value of ratio of electricity consumption of the data center described herein, and the key parameters and the processing mode should be adopted were as shown in FIG. 3. Then, the total electric energy consumption of the data center was calculated according to the formula for calculating the calibration value of the total electricity consumption by utilizing the test data obtained from the characteristic operating points of a data center located in Shanghai (as shown in FIG. 4):

E_{C}=8760×0.084×7392+8760×0.341×7112+8760×0.288×6656+8760×0.365×6948+8760×0.021×6252=60816370(kW·h)

The total annual electricity consumption of information equipment deployed in the data center was calculated according to the formula for calculating the calibration value of electricity consumption of information equipment:

E_{CIT}=8760×0.084×5177+8760×0.341×5161+8760×0.288×5144+8760×0.266×5174+8760×0.021×5065=45191876(kW·h)

The measured value obtained by virtue of characteristic operating condition method was calculated according to the formula for calculating the measured data of ratio of electricity consumption of the data center:

$${R}_{M 1} = \frac{{E}_{C}}{{E}_{CIT}} = \frac{60}{45} \frac{316}{191} \frac{370}{876} = 1.35$$

The following information should be disclosed simultaneously during publishing the measured value of ratio of electricity consumption of the data center which can be obtained by virtue of characteristic operating condition method:

Geographic location of the data center was positioned to the city precisely;

The specific testing period, and all the average values of following items which were corresponding to all valid data points utilized during the same period: i.e., dry-bulb temperature and wet-bulb temperature measured from inside and outside of the data center, the actual operating load of information equipment, and the consumption power of information equipment, and the total power of the data center, should be prepared.

The preceding text only described the preferred embodiment of the present invention, which is just aim at helping others understand the method and the core concept of the present invention. The protection scope of the present invention is not limited to the aforesaid embodiment, all technical schemes developed according to the idea described herein shall fall within the same protection scope of the present invention. For those skilled in the art, it should be understood that any improvement and modification without departing from the principle of the present invention also shall fall within the protection scope of the present invention.

The present invention basically solved the problem that there is no method is available for conducting energy consumption measurement, energy efficiency computing and audit to data centers equipped with independent power distribution equipment, air cooling and electric air conditioning facilities. On condition that the temperature, the relative humidity and the illuminance are accurate, it achieved the computing and audit of energy efficiency of data center by utilizing precise instruments to test the calibration values of the ratio of electricity consumption, the electricity consumption and the total electricity consumption and determine that all the data are subject to relevant requirements.

1. A method for testing energy efficiency of data center, characterized in that consisting of the test conditions, the point positions for testing and the computational formulas, wherein, the test conditions include the test environment and the precision or accuracy of various instruments, and the point positions for testing consist of the point position for measuring electricity consumption, or the point positions for measuring temperature, relative humidity and illuminance. Furthermore, the computational formulas consist of the design value and the measured value of ratio of electricity consumption of the data center and their determination conditions;
The said test environment means that the temperature, the relative humidity, and the illuminance of the data center must be subject to the relevant requirements of GB50174 during testing;
The precision or accuracy of said instruments and meters shall be subject to the following requirements:
The accuracy of electric energy metering instrument shall be in Class 1;
The accuracy of current transformer shall be in Class 0.5;
The accuracy of power meter shall be in Class 0.5;
The accuracy of voltage transformer shall be in Class 0.5;
The accuracy of temperature measuring instrument shall be within ±0.5 ° C.;
The accuracy of relative humidity measuring instrument shall be within ±5%;
The accuracy of illuminometer shall be in class 1 at least, and the relative error of indicating value shall be ≤±4%;
The said point position for measuring electricity consumption must be the position where may collect and regulate the electricity consumption data of the data center as well as can obtain the data required for determining the ratio of electricity consumption of the data center;
The said point positions for measuring temperature, relative humidity and illuminance consist of indoor and outdoor point positions for measuring. Wherein, the indoor point positions for measuring shall be subject to the relevant provisions of GB50462 and the outdoor point positions for measuring shall be centered and lm away from the windward side of the equipment which impacts on the cooling performance. In addition, if there are multiple devices, the mean value of temperature shall be adopted under the condition of avoiding the impact of the cooling equipment on the temperature measurement;
The said design value of ratio of electricity consumption of the data center shall be calculated as per the following formula:
$${R}_{D} = \frac{{E}_{D}}{{E}_{D I T}}$$
Wherein, the R_{D} refers to the design value of ratio of electricity consumption of the data center and the E_{D} refers to the planning design value of total electricity consumption, as well as the E_{DIT} refers to the planning design value of electricity consumption of the information equipment, all of which shall be expressed in kW/h;
The said measured values of ratio of electricity consumption of the data center, consisting of the calibration value of total electricity consumption and the calibration value of electricity consumption of the information equipment, shall be calculated as per the following formula:
S1. According to the actual operating load of the data center, the total power of the data center and the power of information equipment shall be measured continuously respectively based upon selecting different time intervals including the characteristic operating points within a year. Wherein, the continuous measurement must be done for 12 h at least under the stable operation of the refrigeration and information system, meanwhile, the time interval for multiple measurements shall not be more than 2 min. Furthermore, it is prohibited to change the number of servers and the basic facilities including cooling devices and power distribution equipment deployed in the data center, also the refrigeration mode shall not be switched;
S2. The power measured under the test condition that is within ±2° C. of the stable characteristic operating point shall be adopted as valid data, then, the arithmetic means of the total power and the valid data of the power of information equipment shall be calculated respectively, after that, the corresponding power value of such operating point can be worked out;
S3. As to those data centers equipped with data monitoring system of annual electricity consumption and monitoring facility with appropriate accuracy, the annual electricity consumption data shall be measured and recorded at the point positions for measuring electricity consumption, meanwhile, the data of ratio of electricity consumption obtained from two data centers shall be monitored. One of them represents the measured value obtained by virtue of the characteristic operating condition method, which is calculated as per the formula of
$${R}_{M 1} = \frac{{E}_{C}}{{E}_{CIT}}$$
and with the data of total power and the power data of the information equipment collected according to the testing condition related to the ratio of electricity consumption of the data center and the test frequency. The other one represents the annual measured value of the ratio of electricity consumption of the data center, which is calculated with the data of annual electricity consumption as per the formula of
$${R}_{M 2} = \frac{E}{{E}_{IT}} ;$$
The said calibration value of the total electricity consumption shall be calculated as per the following formula:
E_{c}=8760×TₐPₐ+8760×T_{b}P_{b}+8760×T_{c}P_{c}+8760×T_{d}P_{d}+8760×TₑPₑ, wherein, E_{c} represents the calibration value of total electricity consumption, which is expressed in kw/h; and Pa˜Pe represent the total power of the data center measured according to various operating conditions, all of which are expressed in kw; furthermore, Ta˜Te represent the temperature distribution coefficients, which indicate the percent of time of each temperature range represented by characteristic operating point distributed in certain region in the year; and the number 8760 refers to the number of hours in the year, which is expressed in h;
The said calibration value of electricity consumption of the information equipment shall be calculated as per the following formula:
E_{CIT}=8760×TₐP_{aIT}+8760×T_{b}P_{bIT}+8760×T_{c}P_{cIT}+8760×T_{d}P_{dIT}+8760×TₑP_{eIT},
Wherein, E_{cit} represents the calibration value of electricity consumption of the information equipment, which is expressed in kw/h; P_{aIT}˜P_{eIT} represents the power of information equipment deployed in the data center, which is measured under operating conditions and expressed in kw;
The said measured value of ratio of electricity consumption of the data center shall be calculated as per the following formula:
$${R}_{M 1} = \frac{{E}_{C}}{{E}_{CIT}} ,$$
wherein, Rₘ₁ represents the measured value of ratio of electricity consumption of the data center, which is measured by virtue of characteristic operating condition method and according to special operating condition mode; In addition, E_{c} represents the calibration value of total electricity consumption and Ecyr represents the calibration value of electricity consumption of the information equipment, all of which are expressed in kw/h;
$${R}_{M 2} = \frac{E}{{E}_{IT}} ,$$
wherein, Rₘ₂ represents the annual measured value of ratio of electricity consumption of the data center calculated according to the annual electricity consumption, which is non-dimensional; E represents the annual measured value of annual electricity consumption, which is expressed in kw/h;
The said determination conditions consist of:
The design value of ratio of electricity consumption of the data center, the measured value obtained by virtue of characteristic operating condition method and the annual measured value shall be subject to corresponding regulations of value classes;
The measured value of ratio of electricity consumption of the data center obtained by virtue of characteristic operating condition method and the annual measured value shall be less than 1.05 times of the design value.
